(19) United States
(12) Patent Application Publication
(10) Pub. No.: US 2009/0173958 A1
(43) Pub. Date: Jul. 9, 2009

(54) LIGHT EMITTING DEVICES WITH HIGH EFFICIENCY PHOSPOR STRUCTURES

(75) Inventors: Arpan Chakraborty, Goleta, CA (US); Bernd Keller, Santa Barbara, CA (US)

Correspondence Address: MYERS BIGEL SIBLEY & SAJOVEC, P.A., P.O. BOX 37428, RALEIGH, NC, 27627, US

(73) Assignee: Cree, Inc.

(21) Appl. No.: 11/969,508

(22) Filed: Jan. 4, 2008

(51) Int. Cl. H01L 33/00

(52) U.S. Cl. 257/98; 257/E33.001

(57) ABSTRACT

A light emitting device includes a light emitting die configured to emit light having a first dominant wavelength, and an index matched wavelength conversion structure configured to receive light emitted by the light emitting die. The index matched wavelength conversion structure includes wavelength converting particles having a first index of refraction embedded in a matrix material. The matrix material has a second index of refraction that may be substantially matched to the first index of refraction. The light emitting device may include a graded index layer having an index of refraction that is continuously graded from a first index of refraction in a first region of the graded index layer near the light emitting die to a second index of refraction in the graded index layer away from the light emitting die.

### FIELD OF THE INVENTION

This invention relates to solid state light emitting devices and fabrication methods therefor, and more particularly, to wavelength conversion structures used in solid state light emitting devices.

### BACKGROUND OF THE INVENTION

Light emitting diodes and laser diodes are well known solid state lighting elements capable of generating light upon application of a sufficient voltage. Light emitting diodes and laser diodes may be generally referred to as light emitting devices (“LEDs”). Light emitting devices generally include a semiconductor chip, or die, including a p-n junction formed in an epitaxial layer grown on a substrate such as sapphire, silicon, silicon carbide, gallium arsenide and the like. The substrate may subsequently be trimmed, patterned, or removed altogether. The wavelength distribution of the light generated by the LED generally depends on the material from which the p-n junction is fabricated and the structure of the thin epitaxial layers that make up the active region of the device.

The p-n junction semiconductor die is typically enclosed in a package. An LED package can perform a number of functions and provide a number of benefits. For example, an LED package can provide mechanical support and environmental protection for the semiconductor die, as well as providing electrical leads for connecting the die to an external circuit, and heatsinks for efficient heat extraction from the chip. An LED package can also perform optical functions. For example, an LED package can include optical materials and/or structures, such as lenses, reflectors, light scattering layers, etc., that can direct light output by the semiconductor chip in a desired manner.

It is often desirable to incorporate phosphor into a solid state light emitting device package to enhance the emitted radiation in a particular frequency band and/or to convert at least some of the radiation to another frequency band. The term “phosphor” may be used herein to refer to any materials that absorb light at one wavelength and re-emit light at a different wavelength, regardless of the delay between absorption and re-emission and regardless of the wavelengths involved. Accordingly, the term “phosphor” may be used herein to refer to materials that are sometimes called fluorescent and/or phosphorescent. In general, phosphors absorb light having shorter wavelengths and re-emit light having longer wavelengths. As such, some or all of the light emitted by the LED chip at a first wavelength may be absorbed by the phosphor particles, which may responsively emit light at a second wavelength. For example, a single blue emitting LED chip may be surrounded with a yellow phosphor, such as cerium-doped yttrium aluminum garnet (YAG). The resulting light, which is a combination of blue light and yellow light, may appear white to an observer.

While many phosphors are known and used by those of skill in the art, there remains a need for phosphor materials and processes that improve quantum efficiency, reduce scattering, and/or facilitate the manufacturing of solid state light emitting devices that include phosphor.

### SUMMARY OF THE INVENTION

A light emitting device according to some embodiments of the invention includes a light emitting die configured to emit light having a first dominant wavelength, and an index matched wavelength conversion structure configured to receive light emitted by the light emitting die. The index matched wavelength conversion structure may include a plurality of wavelength converting particles embedded in a matrix material. The wavelength converting particles have a first index of refraction and configured to receive at least a portion of light emitted by the light emitting die and to responsively emit light having a second dominant wavelength that may be different from the first dominant wavelength, and the matrix material has a second index of refraction that may be substantially matched to the first index of refraction. As used herein, two materials have indices of refraction that are “substantially matched” if the indices of refraction are within a range of about ±0.2 of each other. In particular, the matrix material may include silicone and may have an index of refraction greater than about 1.55.

The light emitting device may further include a mounting surface. The light emitting die may be on the mounting surface and may be between the mounting surface and the wavelength conversion structure.

The light emitting device may further include a lens on the wavelength conversion structure. The lens may be configured to receive light emitted by the light emitting die that passes through the wavelength conversion structure.

The light emitting device may further include a submount and a lens. The light emitting die may be on the submount, and the light emitting die may be between the submount and the lens. The lens may include a proximal surface near the light emitting device, a distal surface spaced apart from the light emitting device, and a side surface extending between the proximal surface and the distal surface. The wavelength conversion structure may be on the proximal surface, the distal surface, and/or the side surface.

The light emitting device may further include a reflective layer on at least one of the proximal surface, the distal surface or the side surface of the lens that the wavelength conversion structure is not on.

The light emitting device may further include a light scattering layer configured to scatter light emitted by the light emitting die. The light scattering layer may be between the light emitting die and the wavelength conversion structure, or the wavelength conversion structure may be between the light emitting die and the light scattering layer.

The light emitting device may further include a mounting surface with the light emitting die on the mounting surface. The light emitting device may further include a housing including sidewalls extending away from the mounting surface, with the mounting surface and the sidewalls defining an optical cavity. The wavelength conversion structure may be outside the optical cavity.

The light emitting device may further include a lens on the optical cavity. The lens may be between the optical cavity and the wavelength conversion structure. The lens may include a primary lens on the mounting cavity and a secondary lens on the primary lens, the wavelength conversion structure may be on the secondary lens. The primary lens may include a hemispherical lens having a flat surface adjacent the optical cavity and a hemispherical surface opposite the flat surface, and the secondary lens may include a concave surface that may be conformally mated to the hemispherical surface of the primary lens.

The light emitting device may further include an encapsulant material in the optical cavity. The encapsulant material may have a first index of refraction that is lower than a second index of refraction of the lens. A graded index layer may be between the optical cavity and the lens, the graded index layer having an index of refraction that is continuously graded from a lower index near the optical cavity to a higher index near the lens.

The wavelength conversion structure may be between the lens and the optical cavity. The light emitting device may further include a light scattering layer on the optical cavity.

The light emitting device may further include a graded index layer on the wavelength conversion structure, wherein the graded index layer has an index of refraction that is continuously graded from a higher index of refraction near the wavelength conversion structure to a lower index of refraction away from the wavelength conversion structure.

The light emitting device many further include a graded index layer between the wavelength conversion structure and the light emitting die, the graded index layer having an index of refraction that is continuously graded from a higher index of refraction near the light emitting die to a lower index of refraction near the wavelength conversion structure. The graded index layer may have a refractive index equal to or lower than the index of the wavelength conversion structure near the light emitting device.

In some embodiments, the wavelength conversion structure may include a lens positioned adjacent the light emitting die.

The light emitting device may further include a submount. The light emitting die may be on the submount, and the lens may be adhesively attached to the submount over the light emitting die.

A light emitting structure according to some embodiments includes a diode layer and an index matched wavelength conversion structure adhesively bonded to the diode layer. The index matched wavelength conversion structure may include a plurality of wavelength converting particles embedded in a matrix material. The wavelength converting particles have a first index of refraction and are configured to receive at least a portion of light emitted by the light emitting die and to responsively emit light having a second dominant wavelength that is different from the first dominant wavelength. The matrix material has a second index of refraction that may be substantially matched to the first index of refraction.

Some embodiments of the invention provide a light emitting device including a submount, a light emitting die mounted on the submount, an index matched wavelength conversion structure adhesively bonded to the diode layer, and a lens on the wavelength conversion structure. The index matched wavelength conversion structure may include a plurality of wavelength converting particles embedded in a matrix material. The wavelength converting particles have a first index of refraction and are configured to receive at least a portion of light emitted by the light emitting die and to responsively emit light having a second dominant wavelength that may be different from the first dominant wavelength, and the matrix material has a second index of refraction that may be substantially matched to the first index of refraction.

The light emitting device may further include a light scattering layer between the lens and the wavelength conversion structure and that is configured to scatter light emitted by the wavelength conversion structure. The light emitting device may further include an antireflective coating on the lens.

A light emitting device according to further embodiments of the invention includes a light emitting die configured to emit light having a first dominant wavelength, and a graded index layer configured to receive light emitted by the light emitting die. The graded index layer has an index of refraction that is continuously graded from a first index of refraction in a first region of the graded index layer near the light emitting die to a second index of refraction in the graded index layer away from the light emitting die. The first index of refraction is different from the second index of refraction.

The graded index layer may include a silicone matrix including a plurality of transparent particles embedded therein. The silicone matrix may have a first index of refraction and the transparent particles have a second index of refraction that may be higher than the first index of refraction. A concentration of the transparent particles in the silicone matrix may be continuously graded from a first concentration in the first region of the graded index layer near the light emitting die to a second concentration in the graded index layer away from the light emitting die.

The light emitting device may further include an optical element having a third index of refraction that may be higher than the first and second indices of refraction and that may be configured to receive light emitted by the light emitting die. The optical element may be between the light emitting die and the graded index layer. The first region of the graded index of refraction may be near the optical element and the second region of the graded index layer may be away from the optical element, and the first index of refraction may be higher than the second index of refraction.

The optical element may include a lens and/or a wavelength conversion structure. In some embodiments, the wavelength conversion structure may include a single crystal phosphor layer. In other embodiments, the wavelength conversion structure may include a matrix material having a plurality of wavelength converting particles embedded therein, the wavelength converting particles configured to receive at least a portion of light emitted by the light emitting die and to responsively emit light having a second dominant wavelength that may be different from the first dominant wavelength, and the matrix material having a third index of refraction that may be substantially matched to a fourth index of refraction of the wavelength converting particles.

The light emitting device may further include an encapsulant material on the light emitting die. The encapsulant material may have a third index of refraction that may be less than or about equal to the first index of refraction, and the encapsulant material may be between the light emitting die and the graded index layer. The first region of the graded index of refraction may be near the encapsulant material and the second region of the graded index layer may be away from the encapsulant material, and the first index of refraction may be lower than the second index of refraction.

The light emitting device may further include an optical element on the graded index layer, the optical element may have a fourth index of refraction that may be greater than or about equal to the second index of refraction. The optical element may include a lens and/or a wavelength conversion structure.

The wavelength conversion structure may include a single crystal phosphor layer and/or a matrix material having a plurality of wavelength converting particles embedded therein, the matrix material having a fifth index of refraction that is substantially matched to a sixth index of refraction of the wavelength converting particles.

### BRIEF DESCRIPTION OF THE DRAWINGS

FIGS. 1A-1F are cross-sectional views of various configurations of conventional light emitting diodes.

FIG. 1G is a cross-sectional view of a conventional packaged light emitting diode.

FIG. 2 is a cross sectional view of a wavelength conversion structure according to embodiments of the invention.

FIG. 3A is a cross sectional view of an LED structure including a wavelength conversion structure according to embodiments of the invention.

FIG. 3B illustrates singulated LED devices according to embodiments of the invention.

FIG. 4A is a cross sectional view of an LED structure including a wavelength conversion structure according to further embodiments of the invention.

FIG. 4B illustrates singulated LED devices according to further embodiments of the invention.

FIGS. 5A-5C are cross sectional illustrations of LED structures including graded index layers according to embodiments of the invention.

FIGS. 6A-6C illustrate methods of forming LED devices according to embodiments of the invention.

FIG. 7 is a flowchart illustrating operations according to embodiments of the invention.

FIGS. 8A-8E illustrate LED packages according to embodiments of the invention.

FIG. 9 illustrates a packaged LED according to embodiments of the invention.

FIG. 10 is a schematic illustration of a display unit having a backlight including a light emitting device according to some embodiments of the invention.

FIG. 11 is a schematic illustration of a solid state luminaire including a light emitting device according to some embodiments of the invention.

### DETAILED DESCRIPTION OF EMBODIMENTS OF THE INVENTION

The invention will be described more fully hereinafter with reference to the accompanying drawings, in which example embodiments of the invention are shown. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. In the drawings, the size and relative sizes of layers and regions may be exaggerated for clarity. Moreover, each embodiment described and illustrated herein includes its complementary conductivity type embodiment as well. Like numbers refer to like elements throughout.

It will be understood that when an element or layer is referred to as being “on,” “connected to,” “coupled to” or “responsive to” (and/or variants thereof) another element, it can be directly on or directly connected, coupled or responsive to the other element or intervening elements may be present. In contrast, when an element is referred to as being “directly on,” “directly connected to,” “directly coupled to” or “directly responsive to” (and/or variants thereof) another element, there are no intervening elements present. As used herein, the term “and/or” includes any and all combinations of one or more of the associated listed items and may be abbreviated as “/”.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising” (and/or variants thereof), when used in this specification, specify the presence of stated features, integers, steps, operations, elements, and/or components, but do not preclude the presence or addition of one or more other features, integers, steps, operations, elements, components, and/or groups thereof. In contrast, the term “consisting of” (and/or variants thereof) when used in this specification, specifies the stated number of features, integers, steps, operations, elements, and/or components, and precludes additional features, integers, steps, operations, elements, and/or components.

The present invention is described below with reference to block diagrams and/or flowchart illustrations of methods and/or apparatus (systems) according to embodiments of the invention. It is understood that a block of the block diagrams and/or flowchart illustrations, and combinations of blocks in the block diagrams and/or flowchart illustrations, can embody apparatus/systems (structure), means (function) and/or steps (methods) for implementing the functions/acts specified in the block diagrams and/or flowchart block or blocks.

It should also be noted that in some alternate implementations, the functions/acts noted in the blocks may occur out of the order noted in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Example embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, may be expected. Thus, the disclosed example embodiments of the invention should not be construed as limited to the particular shapes of regions illustrated herein unless expressly so defined herein, but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention, unless expressly so defined herein.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and the present application, and will not be interpreted in an idealized or overly formal sense unless expressly so defined herein.

According to some embodiments of the present invention, solid state light emitting devices are provided that include a solid state light emitting die that is configured to emit light upon energization thereof and a phosphor-based wavelength conversion structure arranged to receive light emitted by the solid state light emitting die. In some embodiments, the wavelength conversion structure may be fabricated separately from the solid state light emitting die, and may be subsequently attached to the die. In such cases, the wavelength conversion structure may be referred to as a preform, which may be optionally sized to fit a light emitting surface of the die, and then attached to the light emitting surface, as described in further detail below. The phosphor preform may be adhesively attached to the light emitting die in some embodiments.

A “wavelength conversion structure” is a structure in an LED that includes a phosphor that may absorb light at one wavelength and re-emit light at another wavelength. In some embodiments, the phosphor wavelength conversion structure may include a single crystal phosphor, and in some embodiments may include a single crystal phosphor particle embedded in a high-refractive index material.

The phrase “adhesively attaching” means bonding two elements to one another. The bonding may be direct via a single adhesive layer or via one or more intermediate adhesive and/or other layers/structures, to form a unitary structure of the solid state light emitting die and the phosphor preform that is adhesively attached thereto, such that this unitary structure may be placed on a submount or other packaging element.

The term “transparent” means that optical radiation from the solid state light emitting device can pass through the material without being totally absorbed or totally reflected.

The use of a preformed phosphor wavelength conversion structure, according to various embodiments of the invention, may provide many potential advantages in the fabrication of solid state light emitting devices. For example, it is often desirable to incorporate phosphor and/or other optical elements into the solid state light emitting device. However, when forming a phosphor layer by dispensing a liquid polymer coating containing phosphor particles, the coating may be unduly thick and/or undesirably nonuniform. Moreover, a phosphor layer that is incorporated into a dome or shell also may be too thick and/or nonuniform. In addition, phosphors are generally provided as a polycrystalline powder in a supporting matrix wherein the size and quality of the phosphor particles may significantly affect the quantum efficiency and/or reflective coefficient of the phosphor. Differences in the refractive indices of the phosphor particles and the matrix material can result in undesired scattering of light, which can reduce the light extraction efficiency of the LED package and/or reduce the efficiency of wavelength conversion.

A phosphor wavelength conversion structure may be formed from any suitable phosphor material that is capable of converting light of one wavelength to another wavelength. For example, the phosphor material may be a cerium (Ce) doped single crystal, such as Y₃Al₅O₁₂ (Ce:YAG), in some embodiments. In other embodiments, other phosphors, such as Ce and/or europium (Eu) doped (Ca, Sr, Mg)AlSiN₃; Eu doped Sr₂₋ₓBaₓSiO₄ (BOSE); Ce or Eu doped strontium thio-gallate: or Eu doped alpha-SiAlON, Y₂O₂S, La₂O₂S, silicon garnet, Y₂O₂S or La₂O₂S may be used. In addition, in some embodiments, the phosphors described in European Patent Publication No. 1,696,016 and/or U.S. Patent Publication No. 2007/0075629 may also be used. The single crystal phosphor may also be doped at any suitable level. In some embodiments. Ce and/or Eu is doped into the single crystal phosphor such that the dopant concentration is in a range of about 0.1 to about 20%.

Internal absorption or bounce seen in polymeric wavelength conversion structures may also be reduced by using a phosphor wavelength conversion structure according to some embodiments of the invention. Also, in some embodiments, the phosphor wavelength conversion structure is a preform that can be formed separately from the solid state light emitting die, and so it can be fabricated and tested without impacting the reliability and/or yield of the solid state light emitting die. Finally, some embodiments of the invention can provide a relatively rigid phosphor perform that may allow for more efficient and effective texturization, roughening, etching and/or featuring of the wavelength conversion structure.

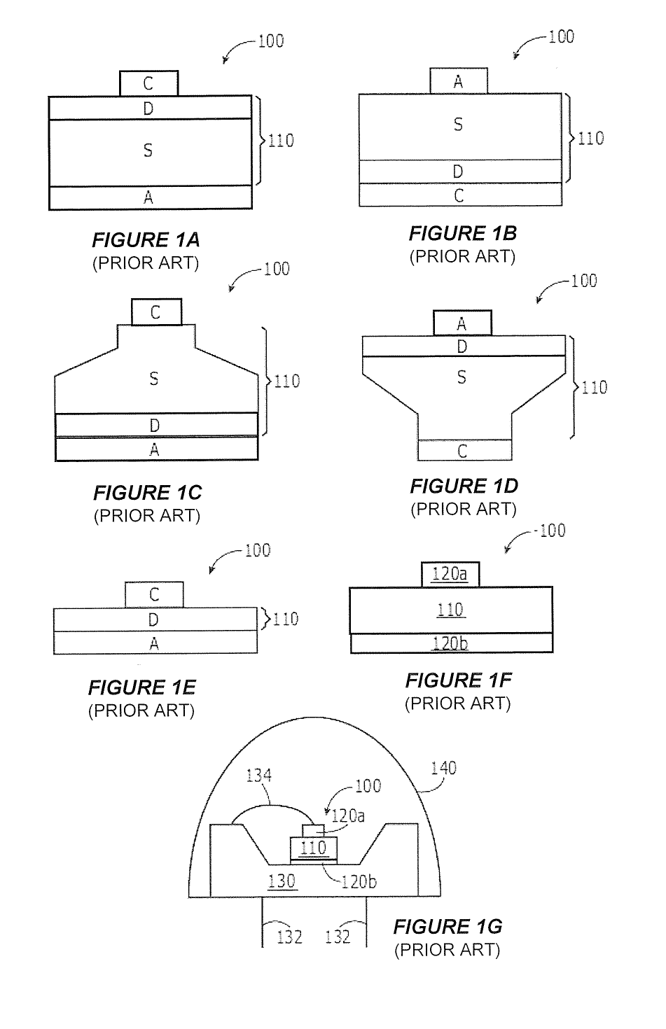

FIGS. 1A-1E are cross-sectional views of various configurations of conventional light emitting diodes (LEDs) that may be used with wavelength conversion structures according to various embodiments of the present invention, optionally in combination with other optical elements. As shown in FIGS. 1A-1E, a solid state light emitting device 100 includes a solid state light emitting die 110 that may comprise a diode region D and a substrate S. The diode region D is configured to emit light upon energization thereof, by applying a voltage between an anode contact A and a cathode contact C. The diode region D may comprise organic and/or inorganic materials. In inorganic devices, the substrate S may comprise silicon carbide, sapphire and/or any other single element and/or compound semiconductor material, and the diode region D may comprise silicon carbide, gallium nitride, gallium arsenide, zinc oxide and/or any other single element or compound semiconductor material, which may be the same as or different from the substrate S. The substrate S may be between about 100 μm and about 250 μm thick, although thinner and thicker substrates may be used or the substrate may not be used at all. The cathode C and anode A contacts may be formed of metal and/or other conductors, and may be at least partially transparent and/or reflective. The design and fabrication of organic and inorganic LEDs are well known to those having skill in the art and need not be described in detail herein. LEDs such as depicted in FIGS. 1A-1E may be marketed by Cree. Inc., the assignee of the present application, for example under the designators XThin®, MegaBright®, EZBright™, UltraThin™, RazerThin®, XBright®, XLamp® and/or other designators and by others.

In FIG. 1A, light emission may take place directly from the diode region D. In contrast, in embodiments of FIG. 1B, emission may take place from diode region D through the substrate S. In FIGS. 1C and ID, the substrate S may be shaped to enhance emission from sidewalls of the substrate S and/or to provide other desirable effects. Finally, in FIG. 1E, the substrate itself may be thinned considerably or eliminated entirely, so that only a diode region D is present. Moreover, in all of the above embodiments, the anode A and cathode C contacts may be of various configurations and may be provided on opposite sides of the solid state light emitting die 110, as illustrated, or on the same side of the solid state light emitting die 110. Multiple contacts of a given type also may be provided.

FIG. 1F provides a generalization of FIGS. 1A-1E, by providing a solid state light emitting device 100 that comprises a solid state light emitting die 110 that includes a diode region D of FIGS. 1A-1E and also may include substrates of FIGS. 1A-1E, and that is configured to emit light upon energization thereof via one or more contacts 120a, 120b. which may include the anode A and cathode C of FIGS. 1A-1E.

FIG. 1G illustrates a solid state light emitting device 100 of FIG. 1F that is packaged by mounting the device 100 on the submount 130 that provides external electrical connections 132 using one or more wire bonds 134 and also provides a protective dome or cover 140. Many other packaging techniques may be employed to package a solid state light emitting die, as is well known to those having skill in the art, and need not be described further herein. For example, packaging techniques are described in U.S. Pat. No. 6,791,119. issued Sep. 14, 2004 to Slater, Jr. et al., entitled Light Emitting Diodes Including Modifications for Light Extraction; U.S. Pat. No. 6,888,167, issued May 3, 2005 to Slater, Jr. et al., entitled Flip-Chip Bonding of Light Emitting Devices and Light Emitting Devices Suitable for Flip-Chip Bonding; U.S. Pat. No. 6,740,906, issued May 24, 2004 to Slater, Jr. et al., entitled Light Emitting Diodes Including Modifications for Submount Bonding: U.S. Pat. No. 6,853,010, issued Feb. 8, 2005 to Slater, Jr. et al., entitled Phosphor-Coated Light Emitting Diodes Including Tapered Sidewalls, and Fabrication Methods Therefor; U.S. Pat. No. 6,885,033, issued Apr. 26, 2005 to Andrews, entitled Light Emitting Devices for Light Conversion and Methods and Semiconductor Chips for Fabricating the Same; and U.S. Pat. No. 7,029,935, issued Apr. 18, 2006 to Negley et al., entitled Transmissive Optical Elements Including Transparent Plastic Shell Having a Phosphor Dispersed Therein, and Methods of Fabricating Same; U.S. Patent Application Publications Nos. 2005/0051789, published Mar. 10, 2005 to Negley et al., Solid Metal Block Mounting Substrates for Semiconductor Light Emitting Devices, and Oxidizing Methods for Fabricating Same; 2005/0212405, published Sep. 29, 2005 to Negley, Semiconductor Light Emitting Devices Including Flexible Film Having Therein an Optical Element, and Methods of Assembling Same; 2006/0018122, published Jan. 26, 2006 to Negley. Reflective Optical Elements for Semiconductor Light Emitting Devices; 2006/0061259, published Mar. 23, 2006 to Negley, Semiconductor Light Emitting Devices Including Patternable Films Comprising Transparent Silicone and Phosphor, and Methods of Manufacturing Same; 2006/0097385, published May 11, 2006 to Negley, Solid Metal Block Semiconductor Light Emitting Device Mounting Substrates and Packages Including Cavities and Heat Sinks, and Methods of Packaging Same; 2006/0124953, published Jun. 15, 2006 to Negley et al., Semiconductor Light Emitting Device Mounting Substrates and Packages Including Cavities and Cover Plates, and Methods of Packaging Same; and 2006/0139945, published Jun. 29, 2006 to Negley et al., Light Emitting Diode Arrays for Direct Backlighting of Liquid Crystal Displays; and U.S. application Ser. No. 11/408,767, filed Apr. 21, 2006 for Villard, Multiple Thermal Path Packaging For Solid State Light Emitting Apparatus And Associated Assembling Methods, all assigned to the assignee of the present invention, the disclosures of which are hereby incorporated herein by reference in their entirety as if set forth fully herein.

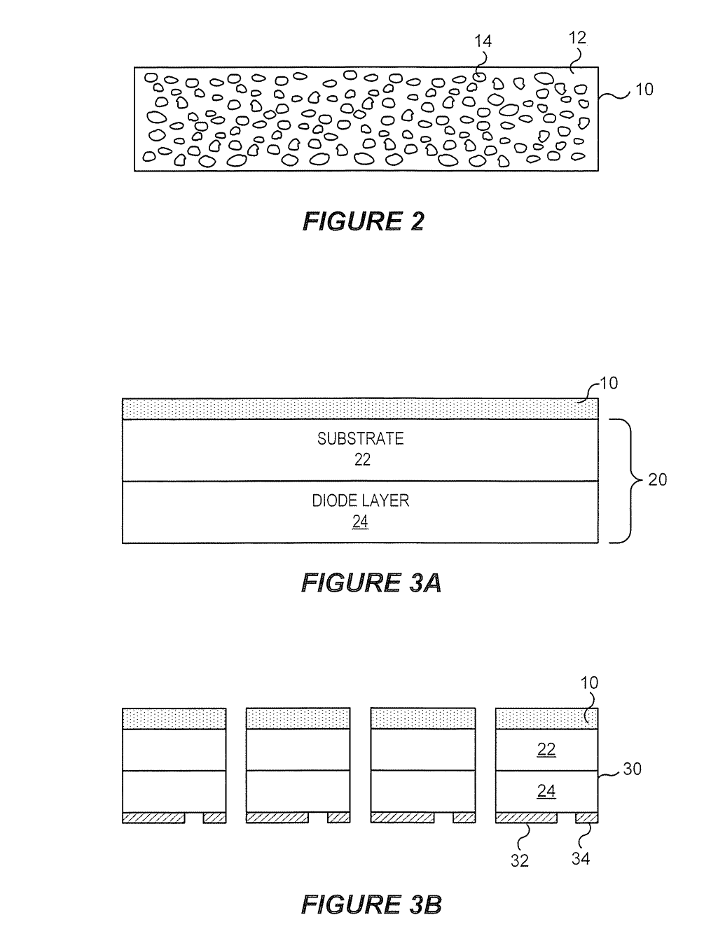

A wavelength conversion structure according to some embodiments of the invention is illustrated in FIG. 2. As shown therein, in some embodiments, a wavelength conversion structure 10 includes a transparent matrix material 12 in which a plurality of light conversion particles 14, such as phosphor particles and/or nanocrystals, is embedded. The transparent matrix material 12 may include a transparent material having an index of refraction that is substantially matched to the index of refraction of the wavelength conversion particles embedded therein. For example, the transparent matrix material may include a high-index silicone. As used herein, “high index silicone” includes silicone materials having an index of refraction of about 1.6 or greater. High index silicone materials are available from, for example, Shin-Etsu Chemical Co., Ltd., Tokyo, Japan.

By providing the wavelength conversion particles 14 in a substantially index-matched matrix material 12, light scattering losses due to differences in the refractive index of the matrix material 12 and the wavelength conversion particles 14 can be reduced and/or eliminated. To the extent that light scattering or redirection is desired in a package, it can be obtained by other potentially more efficient or effective means, such as the inclusion of light scattering layers and/or reflectors that can be included at desired locations within the package. Accordingly, the scattering of light can be separated from the wavelength conversion of the light, which can result in more efficient wavelength conversion, better control over the final pattern of light emission from the package and/or more efficient extraction of light from the package.

In further embodiments, the wavelength conversion structure 10 includes a single crystal phosphor wavelength conversion structure, which is a structure that includes a single crystal phosphor that can absorb light at one wavelength and re-emit light at another wavelength. Single crystal phosphors are described, for example in commonly assigned U.S. patent application Ser. No. 11/749,258 entitled “SINGLE CRYSTAL PHOSPHOR LIGHT CONVERSION STRUCTURES FOR LIGHT EMITTING DEVICES.” filed May 16, 2007, the disclosure of which is incorporated herein by reference as if fully set forth herein. Since single crystal phosphors may not have internal refractive index boundaries, light scattering within a single crystal phosphor wavelength conversion structure may also be reduced and/or avoided.

A wavelength conversion structure 10 according to some embodiments of the invention can be fabricated separately from the LED chip and can be combined with an LED chip in an LED package during manufacturing. For example, a wavelength conversion structure 10 according to some embodiments of the invention can be fabricated separately and subsequently adhesively bonded to an LED structure at the wafer or chip level, or can be mounted within an LED package in order to effect a desired wavelength conversion. Moreover, a wavelength conversion structure 10 according to some embodiments of the invention can be textured and/or patterned to improve light extraction from the LED package by reducing the effects of total internal reflection at an interface of the wavelength conversion structure 10 with an adjacent medium.

Accordingly, it will be appreciated that a wavelength conversion structure 10 according to some embodiments of the invention can be fabricated and tested independently of an LED chip that is mounted in an LED package. Thus, defective wavelength conversion structures can be identified and discarded before packaging, potentially increasing yields and/or decreasing production costs.

In some embodiments, the wavelength conversion structure 10 includes a silicone matrix 12 including a plurality of phosphor particles 14 embedded therein as wavelength conversion particles. Phosphor particles, such as YAG phosphor particles, typically have an index of refraction of about 1.8.

In some embodiments, the wavelength conversion structure 10 includes a silicone matrix 12 including a plurality of nanocrystals therein as wavelength conversion particles. The nanocrystals can include, for example, TiO₂ particles having a diameter that small compared to a wavelength of light passing through the wavelength conversion structure 10.

According to still further embodiments, a wavelength conversion structure including a high-index silicone matrix having embedded light conversion particles can be formed directly on an LED wafer, for example by spin coating the material in liquid form onto the wafer.

Methods of fabricating LED chips/dice according to some embodiments of the invention are illustrated in FIGS. 3A and 3B. As shown therein, an LED wafer 20 including a transparent substrate 22 and a diode layer 24 is provided. The transparent substrate 22 can include a growth substrate (i.e., a semiconductor substrate on which the diode layer is epitaxially grown) and/or a carrier substrate to which the diode layer 24 may be bonded. For example, the diode layer 24 can be grown on a sacrificial growth substrate (not shown). The diode layer 24 can be wafer bonded to a carrier substrate, and the sacrificial growth substrate can be removed. Substrate removal techniques are described, for example, in U.S. Patent Publication No. 2006/0189098, entitled “SUBSTRATE REMOVAL PROCESS FOR HIGH LIGHT EXTRACTION LEDS,” published Aug. 24, 2006, the disclosure of which is incorporated herein by reference as if fully set forth herein.

A wavelength conversion structure 10 can be fabricated independently of the LED wafer 20, and can be bonded, for example by wafer bonding or adhesive bonding, to the LED wafer 20, as shown in FIG. 3A. In some embodiments, the wavelength conversion structure 10 can include a layer of high-index silicone that is embedded with light conversion particles. The high-index silicone layer can be spin-coated onto the LED wafer and cured to form the wavelength conversion structure 10.

Referring to FIG. 3B, individual LED chips 30 may be formed by dicing the LED wafer 20 including the wavelength conversion structure 10. Conventional dicing techniques, such as sawing and/or laser dicing, can be used to singulate the LED chips 30. A plurality of anode and cathode ohmic contacts 32, 34 may be formed on the diode layer D. In some embodiments, the ohmic contacts may be formed prior to bonding the wavelength conversion structure 10 to the LED wafer 20. Accordingly, an LED chip 30 may be suitable for flip-chip mounting in an LED package whereby light can be extracted through the transparent substrate 22.

In some embodiments, an anode and/or cathode ohmic contact can be formed on the substrate 22, for example, before bonding the wavelength conversion structure to the substrate 22. Openings can then be etched in the wavelength conversion structure to expose the ohmic contacts.

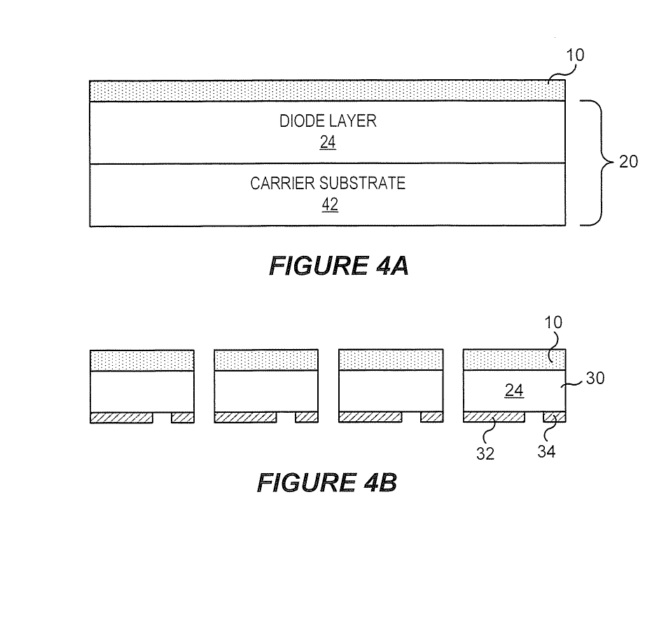

Methods of fabricating LED chips/dice according to further embodiments of the invention are illustrated in FIGS. 4A and 4B. As shown in FIGS. 4A and 4B, the diode layer 24 can be bonded to a carrier substrate 42, for example through adhesive bonding. The wavelength conversion structure 10 can be bonded to the diode layer 24. The carrier substrate 42 can subsequently be removed from the diode layer 24 and the diode layer and wavelength conversion structure can be diced to provide individual LED chips 40. Furthermore, anode and cathode contacts 32, 34 can be formed on the diode layer 24 to facilitate electrical connection of the LED chip to an external circuit and/or an LED package.

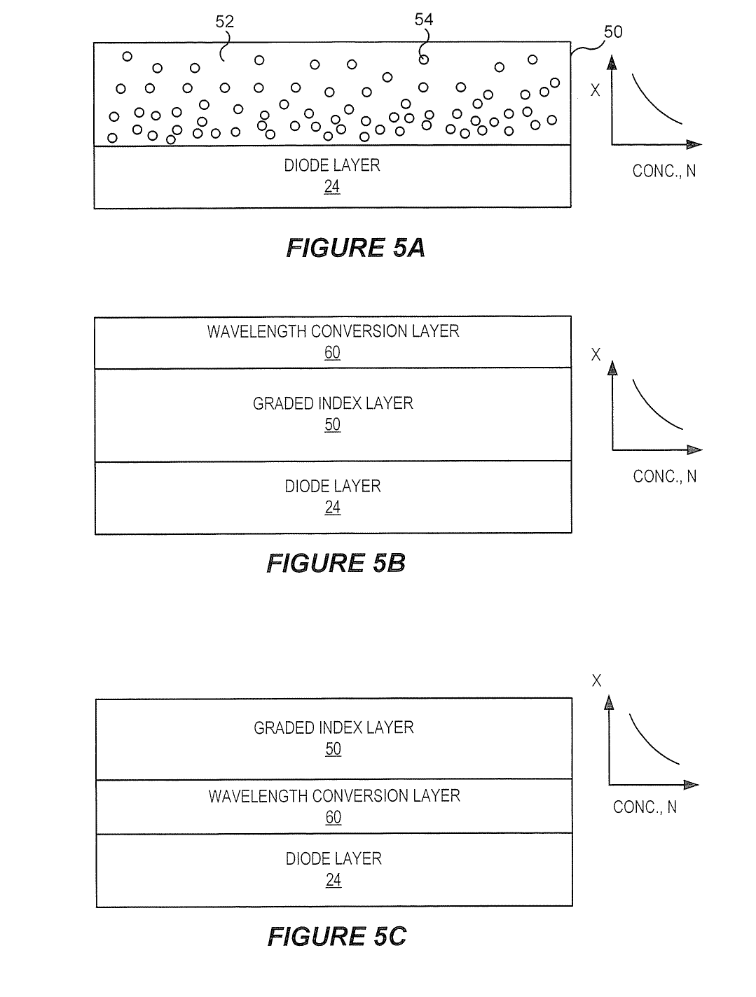

In some applications, it may be desirable for an LED package to include an encapsulant material or layer on an LED chip that provides a substantial index match to both a high-index material, such as a diode layer 24, as well as a substantial index match to a lower index material, such as conventional silicone. Accordingly, referring to FIGS. 5A and 5B, some embodiments of the invention provide a graded index layer 50 that has a continuously graded index of refraction. In particular, the graded index layer 50 can include a matrix material 52 having a high or midrange index of refraction. As used herein, a midrange index of refraction means an index of refraction between about 1.54 and 1.65. Index modifying particles 54 having an index of refraction higher than the index of refraction of the matrix material 52 are embedded in the matrix material 52.

As illustrated in FIG. 5A, the concentration of the index modifying particles 54 changes continuously with the thickness of the graded index layer 50 so that the concentration of the index modifying particles 54 is greater in one part of the graded index layer 50 than in another part of the graded index layer 50. For example, as illustrated in FIG. 5A, a graded index layer 50 is provided on a diode layer 24. The diode layer 24 may include a semiconductor material, such as gallium nitride, having a relatively high index of refraction. The graded index layer 50 can include a matrix material 52 of, for example, silicone having an index of refraction of about 1.5. Embedded in the silicone matrix 52 are particles 54 of an index modifying material, such as TiO₂, SiO₂, and/or phosphor particles, which can have an index of refraction of about 1.8 or higher.

As illustrated in FIG. 5A, the concentration of particles 54 in the matrix 52 is highest near the interface between the graded index layer 50 and the diode layer 24, and decreases with distance away from the diode layer 24. Accordingly, the index of refraction N of the graded index layer 50 is highest near the interface between the graded index layer 50 and the diode layer 24, and decreases continuously with distance away from the diode layer 24, as illustrated in the graph accompanying FIG. 5A. The grading can include linear and/or nonlinear changes in the index refraction of the graded index layer 50.

The index modifying particles 54 in the gradient creation layer may or may not perform wavelength conversion. Accordingly, as shown in FIGS. 5B and 5C, a separate wavelength conversion layer 60 can be provided on the graded index layer 50. For example, as shown in FIG. 5B, a wavelength conversion layer 60 can be provided on the gradient creation layer 50. This configuration may be useful when the wavelength conversion layer 60 includes a lower index material, such as conventional silicone having an index of refraction of about 1.5. In some embodiments, the wavelength conversion layer can include a wavelength conversion structure 10 as described above.

As shown in FIG. 5C, in some embodiments, the graded index layer 50 may be provided on the wavelength conversion layer 60, so that the wavelength conversion layer 60 is between the diode layer 24 and the gradient creation layer 50. This configuration may be suitable when a high index material, such as a single crystal phosphor material and/or a high index silicone material, is used in the wavelength conversion layer 60.

A graded index layer 50 can be formed by dispensing a layer of liquid silicone that contains gradient-modifying particles 54, and allowing the particles 54 to partially settle within the liquid silicone prior to curing. That is, conventional manufacturing techniques that utilize silicone embedded with phosphors or other particles typically attempt to form a layer of silicone having a uniform composition. In contrast, some embodiments of the invention take advantage of the tendency of particles suspended in liquid silicone to settle over time before curing, to thereby create a layer 50 having a nonuniform composition. For example, in some embodiments, a liquid silicone including high-index particles can be dispensed and allowed to sit for at least an hour before curing in order to provide a suitable amount of settling in the matrix. When cured, the bottom portion of the silicone matrix will have a higher concentration of particles due to settling, and the concentration of particles in the matrix will decrease upwards. Accordingly, the index of refraction of the cured layer will also decrease continuously upwards.

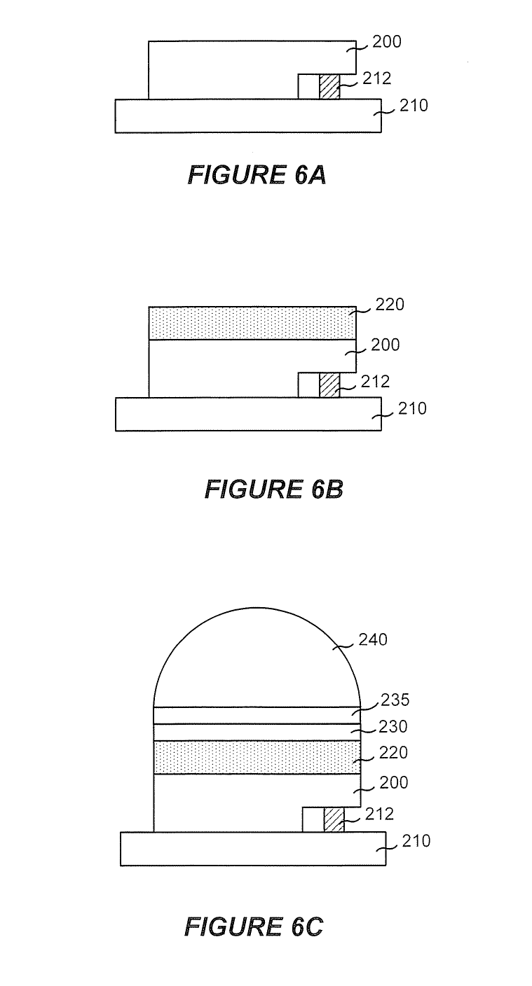

Further embodiments of the invention are illustrated in FIGS. 6A-6C, which are cross-sectional views illustrating packaging of flip-chip light emitting devices according to some embodiments of the invention. Referring to FIG. 6A, an LED chip 200 is flip-chip mounted on a submount 210. The submount 210 can include a ceramic material having a high thermal conductivity, such as aluminum nitride, metal, silicon, or any other suitable material. An ohmic contact 212 connects a contact of the LED chip 200 to a metal trace (not shown) on the submount 210. As shown in FIG. 6B, a wavelength conversion layer 220 is bonded onto the LED chip 200 opposite the submount 210. Referring to FIG. 6C, an optional graded index layer 230 is bonded to the wavelength conversion layer 220. As illustrated in FIG. 6C, the wavelength conversion layer 220 can be positioned between the graded index layer 230 and the LED chip 200. However, in some embodiments, the graded index layer 230 can be positioned between the LED chip 200 and the wavelength conversion layer 220.

A light scattering layer 235 can be provided on the LED chip 200, for example, on the graded index layer 230 and/or the wavelength conversion layer 220.

Finally, an optional lens 240 is bonded to the LED chip 200. The lens 240 can be bonded to the LED chip 200 using, for example, an adhesive. The lens 240 can be formed of glass, silicone, polyacrylate or any other suitable material, and can be shaped to produce a desired light emission pattern. In some embodiments, an antireflective coating may be provided on the surface of the lens 240 to reduce light loss at the lens-air interface due to Fresnel reflection.

The adhesive may be a liquid silicone that may be dispensed onto the single wavelength conversion layer 220, the graded index layer 230 and/or the lens 240 prior to attachment of the lens 240 to the LED chip 210, and then cured after attachment of the lens 240. For example, a silicone-based liquid epoxy may be dispensed at room temperature and spread using the pick and place force of the lens 240 placement. Curing may then take place by heating in an oven.

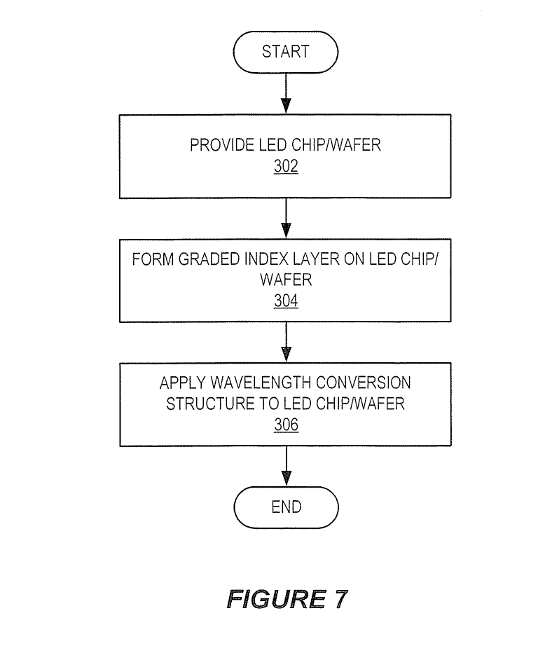

Packaging operations according to some embodiments of the invention are illustrated in FIG. 7. An LED chip or wafer is provided (Block 302). An optional graded index layer is formed on the LED chip/wafer (Block 304). In some embodiments, the graded index layer can be formed independently of the LED chip/wafer and applied as a preform to the LED chip/wafer. In further embodiments, the graded index layer can be formed by spin coating a liquid silicone including index modifying particles onto an LED wafer and allowing the index modifying particles to settle before curing. In another embodiment, the graded index layer can be formed by dispensing a liquid silicone including index modifying particles onto an LED wafer and allowing the index modifying particles to settle before curing.

A wavelength conversion structure is applied to the LED chip/wafer (Block 306). As noted above, the wavelength conversion structure can be formed independently of the LED chip/wafer and applied as a preform to the LED chip/wafer, or, in some embodiments, can be formed directly on an LED wafer by spin coating.

Many other optical elements may be provided in combination with a wavelength conversion structure, according to various embodiments of the present invention. In general, an optical element may be configured to modify at least some of the light that is emitted from the solid state light emitting die by changing its amplitude, frequency and/or direction. These optical elements may include an additional wavelength conversion structure including polycrystalline phosphor particles, an optical refracting element such as a lens, an optical filtering element such as a color filter, an optical scattering element such as optical scattering particles, an optical diffusing element such as a textured surface and/or an optical reflecting element such as a reflective surface, that is included in and/or on the single crystal phosphor wavelength conversion structure. Combinations of these and/or other embodiments may be provided. Moreover, two or more single crystal phosphor wavelength conversion structures may be provided, wherein each single crystal phosphor wavelength conversion structure can perform a different optical processing function, the same optical processing function or overlapping processing functions, depending upon the desired functionality of the solid state light emitting device.

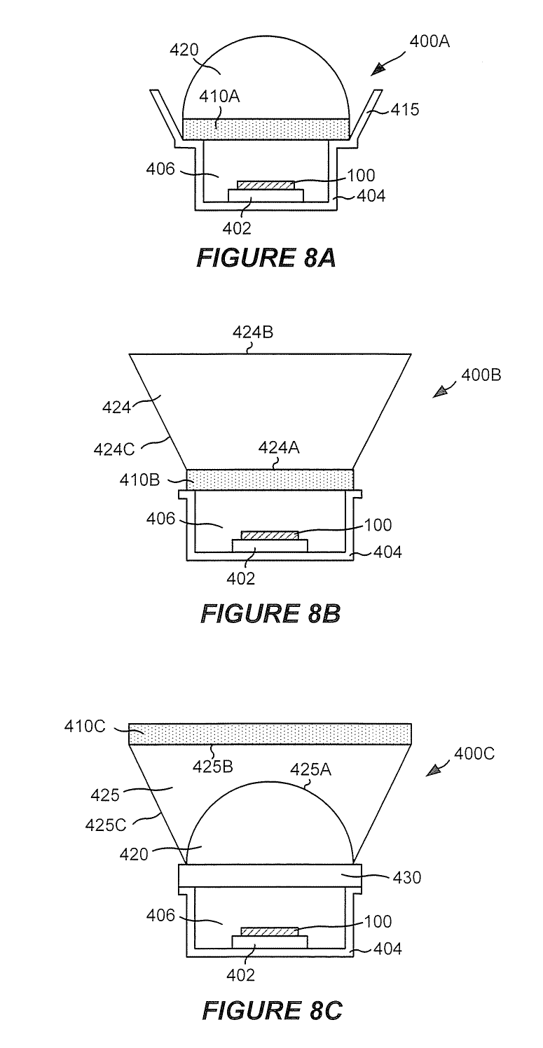

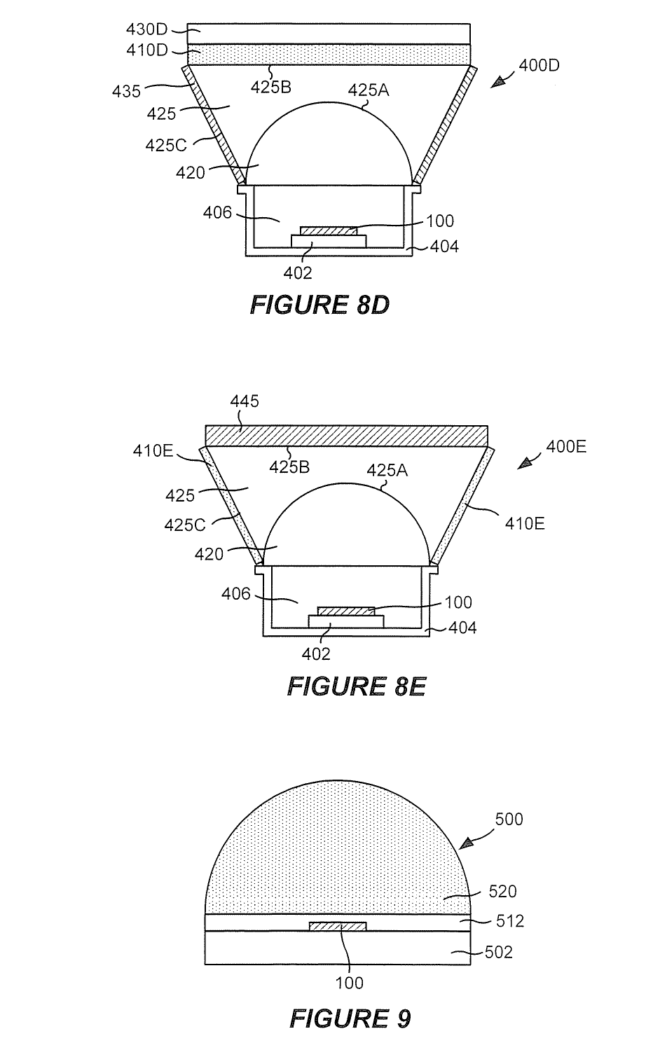

FIGS. 8A to 8E are cross-sectional views of packaged devices according to various embodiments of the present invention. In FIGS. 8A to 8E, common reference numbers are used for similar elements. Referring to FIG. 8A, a packaged LED 400A includes an LED chip 100 mounted on a submount 402. The LED chip 100 and submount 402 are mounted at the base of a cup 404 which defines an optical cavity 406 above the LED chip 100. The cup 404 may be formed of and/or coated with a reflective metal such as aluminum and/or silver. The optical cavity 406 may be filled with an encapsulant material, such as silicone and/or epoxy.

A wavelength conversion structure 410A is positioned over the cup 404 and covers the optical cavity 406, so that light escaping from the optical cavity 406 passes through the wavelength conversion structure 410A. At least some light passing through the wavelength conversion structure 410A may be converted from a first wavelength to a second wavelength, as described above. A lens 420 is positioned over the wavelength conversion structure 410A, and directs light emitted by the LED chip 100 through the wavelength conversion structure 410A in a desired manner. As further illustrated in FIG. 8A, an optional angled reflector 415 may be provided on the cup 404 for additional control of the optical emission pattern of the package 408.

It will be understood that the distance between the LED chip 100 and the wavelength conversion structure 410A may be varied according to the configuration of the LED chip 100, the submount 402 and the cup 404.

Many other optical elements may be provided in combination with the single crystal phosphor light conversion structure, according to various embodiments of the present invention. As discussed above, an optical element may be configured to modify at least some of the light that is emitted from the LED chip 100, by changing the amplitude, frequency and/or direction of the light. These optical elements may include an additional wavelength conversion structure, an index matching structure, such as a graded index layer, an optical refracting element such as a lens, an optical filtering element such as a color filter, an optical scattering element such as optical scattering particles, an optical diffusing element such as a textured surface and/or an optical reflecting element such as a reflective surface. Combinations of these and/or other embodiments may be provided. Moreover, two or more wavelength conversion structures may be provided, wherein each wavelength conversion structure can perform a different optical processing function, the same optical processing function or overlapping processing functions, depending upon the desired functionality of the solid state light emitting device. Many other examples will now be described in detail.

A packaged LED 400B according to further embodiments of the invention is illustrated in FIG. 8B. As shown therein, a trapezoidal lens 424 may be provided on the wavelength conversion structure 410B. In the embodiments illustrated in FIG. 8B, the trapezoidal lens 424 includes a proximal surface 424A that is positioned adjacent the wavelength conversion structure 410B, a distal surface 424B that is remote from the wavelength conversion structure 410B, and angled side surfaces 424C that extend from the proximal surface 424A to the distal surface 424B. A trapezoidal lens, such as trapezoidal lens 424, may provide a different light emission pattern compared to a conventional hemispherical lens.

A packaged LED 400C according to further embodiments of the invention is illustrated in FIG. 8C. As shown therein, a graded index layer 430 may be provided on the cup 404, and a hemispherical primary lens 420 is on the graded index layer 430. The graded index layer 430 may be provided to provide an index match between and encapsulant material in the optical cavity 406 and the primary lens 420.

As further shown in FIG. 8C, a quasi-trapezoidal secondary lens 425 may be provided on the hemispherical primary lens 420. The quasi-trapezoidal secondary lens 425 includes a concave surface 425A that is conformally mated to the hemispherical surface of the primary lens 420, a distal surface 424B that is remote from the primary lens 420, and angled side surfaces 425C that extend from the concave surface 425A to the distal surface 425B. A wavelength conversion structure 410C is provided on the distal surface 425B.

A packaged LED 400D according to further embodiments of the invention is illustrated in FIG. 8D. As shown therein, a wavelength conversion structure 410D is provided on the distal surface 425B of the secondary lens 425. A reflective layer or coating 435 is formed on the angled surface 425C to reflect light upwards and through the wavelength conversion structure 410D.

An optional graded index layer 430D is provided on the wavelength conversion structure 410D. The graded index layer for 430D may provide an index match to the wavelength conversion structure 410D, which may increase light extraction from the package 400D.

In the packaged LED 400E illustrated in FIG. 8E, a reflector or reflective coating 445 is provided on the distal surface 425B of the secondary lens 425, and a wavelength conversion structure 410E is provided on the side surface 425C of the secondary lens 425. Accordingly, light is extracted through the side surface 425C of the secondary lens 425.

Further embodiments of the invention are illustrated in FIG. 9. As shown therein, an LED package 500 includes an LED chip 100 mounted on a submount 502. A wavelength conversion structure 520 is provided on the LED chip 100 and the submount 502. The wavelength conversion structure 520 is formed, for example, of silicone that is cast in a lens shape. The wavelength conversion structure 520 can be attached to the substrate, for example, using a thin layer of silicone epoxy 512.

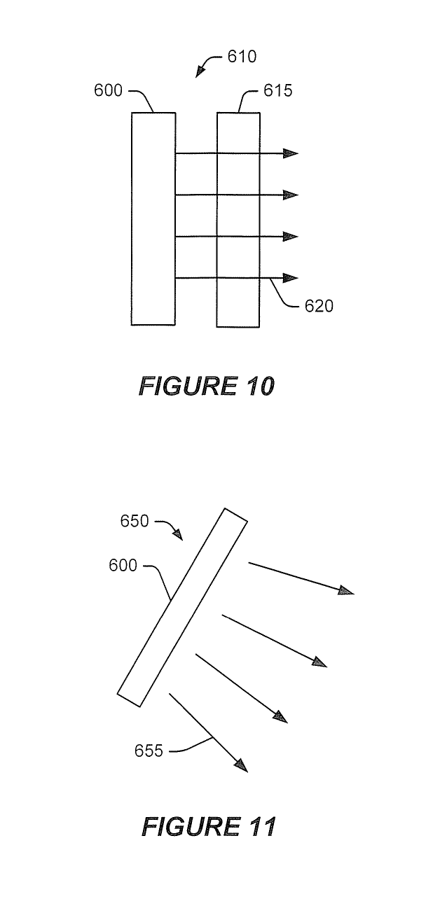

The light emitting devices provided according to some embodiments of the invention may be used in many lighting applications. For example, referring to FIG. 10, a lighting panel 600 including a plurality of light emitting devices according to some embodiments of the invention may be used as a backlight for a display such as a liquid crystal display (LCD) 610. As shown in FIG. 10, an LCD 610 may include a lighting panel 600 that is positioned relative to an LCD screen 615 such that light 620 emitted by the lighting panel 600 passes through the LCD screen 615 to provide backlight for the LCD screen 615. The LCD screen 615 includes appropriately arranged shutters and associated filters that are configured to selectively pass/block a selected color of light 620 from the lighting panel 600 to generate a display image. The lighting panel 600 may include a plurality of light emitting devices according to any of the embodiments described herein.

As an additional example, referring to FIG. 11, a lighting panel 600 including a plurality of light emitting devices according to some embodiments of the invention may be used as a lighting panel for a solid state lighting fixture or luminaire 650. Light 655 emitted by the luminaire 650 may be used to illuminate an area and/or an object. Solid state luminaires are described, for example, in U.S. patent application Ser. No. 11/408,648, filed Apr. 21, 2006, entitled Solid State Luminaires for General Illumination, which is assigned to the assignee of the present invention and the disclosure of which is incorporated herein by reference in its entirety.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

In the drawings and specification, there have been disclosed embodiments of the invention and, although specific terms are employed, they are used in a generic and descriptive sense only and not for purposes of limitation, the scope of the invention being set forth in the following claims.

That which is claimed is:

1. A light emitting device, comprising:
a light emitting die configured to emit light having a first dominant wavelength; and
an index matched wavelength conversion structure configured to receive light emitted by the light emitting die;
wherein the index matched wavelength conversion structure comprises a plurality of wavelength converting particles embedded in a matrix material, the wavelength converting particles having a first index of refraction and configured to receive at least a portion of light emitted by the light emitting die and to responsively emit light having a second dominant wavelength that is different from the first dominant wavelength, and the matrix material having a second index of refraction that is substantially matched to the first index of refraction.

2. The light emitting device of claim 1, wherein the matrix material comprises silicone and has an index of refraction greater than about 1.55.

3. The light emitting device of claim 1, further comprising a mounting surface, wherein the light emitting die is on the mounting surface and is between the mounting surface and the wavelength conversion structure.

4. The light emitting device of claim 1, further comprising a lens on the wavelength conversion structure, wherein the lens is configured to receive light emitted by the light emitting die that passes through the wavelength conversion structure.

5. The light emitting device of claim 1, further comprising:
a submount, wherein the light emitting die is on the submount; and
a lens, wherein the light emitting die is between the submount and the lens, the lens including a proximal surface near the light emitting device, a distal surface spaced apart from the light emitting device, and a side surface extending between the proximal surface and the distal surface, wherein the wavelength conversion structure is on the proximal surface, the distal surface, and/or the side surface.

6. The light emitting device of claim 5, further comprising:
a reflective layer on at least one of the proximal surface, the distal surface and/or the side surface of the lens that the wavelength conversion structure is not on.

7. The light emitting device of claim 1, further comprising a light scattering layer configured to scatter light emitted by the light emitting die.

8. The light emitting device of claim 7, wherein the wavelength conversion structure is between the light emitting die and the light scattering layer.

9. The light emitting device of claim 1, further comprising:
a mounting surface, wherein the light emitting die is on the mounting surface; and
a housing comprising sidewalls extending away from the mounting surface, the mounting surface and the sidewalls defining an optical cavity, wherein the wavelength conversion structure is outside the optical cavity.

10. The light emitting device of claim 9, further comprising a lens on the optical cavity.

11. The light emitting device of claim 10, wherein the lens is between the optical cavity and the wavelength conversion structure.

12. The light emitting device of claim 11, wherein the lens comprises a primary lens on the mounting cavity and a secondary lens on the primary lens, wherein the wavelength conversion structure is on the secondary lens.

13. The light emitting device of claim 12, wherein the primary lens comprises a hemispherical lens having a flat surface adjacent the optical cavity and a hemispherical surface opposite the flat surface, and the secondary lens comprises a concave surface that is conformally on the hemispherical surface of the primary lens.

14. The light emitting device of claim 10, further comprising an encapsulant material in the optical cavity, the encapsulant material having a third index of refraction that is lower than a fourth index of refraction of the lens, and a graded index layer between the optical cavity and the lens, wherein the graded index layer has an index of refraction that is continuously graded from a lower index near the optical cavity to a higher index near the lens.

15. The light emitting device of claim 10, wherein the wavelength conversion structure is between the lens and the optical cavity.

16. The light emitting device of claim 10, further comprising a light scattering layer on the optical cavity.

17. The light emitting device of claim 1, further comprising a graded index layer on the wavelength conversion structure, the graded index layer having an index of refraction that is continuously graded from a higher index of refraction near the wavelength conversion structure to a lower index of refraction away from the wavelength conversion structure.

18. The light emitting device of claim 1, further comprising a graded index layer between the wavelength conversion structure and the light emitting die, the graded index layer having an index of refraction that is continuously graded from a higher index of refraction near the light emitting die to a lower index of refraction near the wavelength conversion structure.

19. The light emitting device of claim 18, wherein the graded index layer has a refractive index equal to the index of the wavelength conversion structure near the light emitting device.

20. The light emitting device of claim 18, wherein the graded index layer has a refractive index lower than the index of the wavelength conversion structure near the interface of the graded index layer and the wavelength conversion layer.

21. The light emitting device of claim 1, wherein the wavelength conversion structure comprises a lens positioned adjacent the light emitting die.

22. The light emitting device of claim 21, further comprising a submount wherein the light emitting die is on the submount, and the lens is adhesively attached to the submount over the light emitting die.

23. A luminaire comprising a light emitting device as recited in claim 1.

24. A liquid crystal display backlight comprising a light emitting device as recited in claim 1.

25. A light emitting structure comprising a diode layer and an index matched wavelength conversion structure adhesively bonded to the diode layer, wherein the index matched wavelength conversion structure comprises a plurality of wavelength converting particles embedded in a matrix material, the wavelength converting particles having a first index of refraction and configured to receive at least a portion of light emitted by the light emitting die and to responsively emit light having a second dominant wavelength that is different from the first dominant wavelength, and the matrix material having a second index of refraction that is substantially matched to the first index of refraction.

26. A light emitting device, comprising:
a submount;
a light emitting die on the submount:
an index matched wavelength conversion structure adhesively bonded to the diode layer, wherein the index matched wavelength conversion structure comprises a plurality of wavelength converting particles embedded in a matrix material, the wavelength converting particles having a first index of refraction and configured to receive at least a portion of light emitted by the light emitting die and to responsively emit light having a second dominant wavelength that is different from the first dominant wavelength, and the matrix material having a second index of refraction that is substantially matched to the first index of refraction; and
a lens on the wavelength conversion structure.

27. The light emitting device of claim 26, further comprising:
a light scattering layer between the lens and the wavelength conversion structure and configured to scatter light emitted by the wavelength conversion structure.

28. The light emitting device of claim 26, further comprising an antireflective coating on the lens.

29. A light emitting device, comprising:
a light emitting die configured to emit light having a first dominant wavelength; and
a graded index layer configured to receive light emitted by the light emitting die, wherein the graded index layer has an index of refraction that is continuously graded from a first index of refraction in a first region of the graded index layer near the light emitting die to a second index of refraction in the graded index layer away from the light emitting die, wherein the first index of refraction is different from the second index of refraction.

30. The light emitting device of claim 29, wherein the graded index layer comprises a silicone matrix including a plurality of transparent particles embedded therein, wherein the silicone matrix has a first index of refraction and the transparent particles have a second index of refraction that is higher than the first index of refraction, and wherein a concentration of the transparent particles in the silicone matrix is continuously graded from a first concentration in the first region of the graded index layer near the light emitting die to a second concentration in the graded index layer away from the light emitting die.

31. The light emitting device of claim 29, further comprising:
an optical element having a third index of refraction that is higher than the first and second indices of refraction and that is configured to receive light emitted by the light emitting die:
wherein the optical element is between the light emitting die and the graded index layer; and
wherein the first region of the graded index of refraction is near the optical element and the second region of the graded index layer is away from the optical element, and wherein the first index of refraction is higher than the second index of refraction.

32. The light emitting device of claim 31, wherein the optical element comprises a lens.

33. The light emitting device of claim 31, wherein the optical element comprises a wavelength conversion structure.

34. The light emitting device of claim 33, wherein the wavelength conversion structure comprises a single crystal phosphor layer.

35. The light emitting device of claim 33, wherein the wavelength conversion structure comprises a matrix material having a plurality of wavelength converting particles embedded therein, the wavelength converting particles configured to receive at least a portion of light emitted by the light emitting die and to responsively emit light having a second dominant wavelength that is different from the first dominant wavelength, and the matrix material having a third index of refraction that is substantially matched to a fourth index of refraction of the wavelength converting particles.

36. The light emitting device of claim 29, further comprising:
an encapsulant material on the light emitting die, wherein the encapsulant material has a third index of refraction that is less than or about equal to the first index of refraction;
wherein the encapsulant material is between the light emitting die and the graded index layer; and
wherein the first region of the graded index of refraction is near the encapsulant material and the second region of the graded index layer is away from the encapsulant material, and wherein the first index of refraction is lower than the second index of refraction.

37. The light emitting device of claim 36, further comprising an optical element on the graded index layer, wherein the optical element has a fourth index of refraction that is greater than or about equal to the second index of refraction.

38. The light emitting device of claim 37, wherein the optical element comprises a lens.

39. The light emitting device of claim 37, wherein the optical element comprises a wavelength conversion structure.

40. The light emitting device of claim 39, wherein the wavelength conversion structure comprises a single crystal phosphor layer.

41. The light emitting device of claim 39, wherein the wavelength conversion structure comprises a matrix material having a plurality of wavelength converting particles embedded therein, the wavelength converting particles configured to receive at least a portion of light emitted by the light emitting die and to responsively emit light having a second dominant wavelength that is different from the first dominant wavelength, and the matrix material having a fifth index of refraction that is substantially matched to a sixth index of refraction of the wavelength converting particles.

42. A luminaire comprising a light emitting device as recited in claim 29.

43. A liquid crystal display backlight comprising a light emitting device as recited in claim 29.
